(19) United States
(12) Patent Application Publication
(10) Pub. No.: US 2026/0186060 A1
(43) Pub. Date: Jul. 2, 2026

(54) APPARATUS AND METHOD FOR DETECTING AN ABNORMALITY IN A BATTERY PACK

(71) Applicants: HYUNDAI MOTOR COMPANY, Seoul (KR); KIA CORPORATION, Seoul (KR)

(72) Inventors: Yoon Sung Choi, Hwaseong-si (KR); Hyo Kyung Lee, Hwaseong-si (KR); Jae Won Kim, Hwaseong-si (KR)

(73) Assignees: HYUNDAI MOTOR COMPANY, Seoul (KR); KIA CORPORATION, Seoul (KR)

(21) Appl. No.: 19/295,088

(22) Filed: Aug. 8, 2025

(30) Foreign Application Priority Data
Dec. 31, 2024 (KR) 10-2024-0202724

(51) Int. Cl. G01R 31/367; B60L 58/16; G01R 31/36; G01R 31/388; G01R 31/392

(52) U.S. Cl. CPC G01R 31/367; B60L 58/16; G01R 31/3648; G01R 31/388; G01R 31/392

(57) ABSTRACT

A method for detecting abnormality in battery pack based on a battery model and an apparatus therefor are provided. A computing device includes a memory configured to store instructions; and a processor. The processor is configured, by executing the instructions, to set a battery model corresponding to a battery pack; estimate a battery voltage based on the set battery model; measure a real battery voltage; determine a battery pack voltage deviation based on the real battery voltage; determine a model estimation error based on the battery voltage and the real battery voltage; set a threshold based on the model estimation error; and compare the battery pack voltage deviation with the threshold to determine whether the battery pack is abnormal.

### CROSS-REFERENCE TO RELATED APPLICATION

This application claims the benefit of and priority to Korean Patent Application No. 10-2024-0202724, filed in the Korean Intellectual Property Office on Dec. 31, 2024, the entire contents of which are incorporated herein by reference.

### TECHNICAL FIELD

The present disclosure relates to a technology for detecting abnormality in battery pack. More particularly, the present disclosure relates to technologies for detecting whether a battery pack is abnormal based on a battery model on an on-board vehicle or via interworking with a cloud server.

### BACKGROUND

Today, new renewable energy has become necessary rather than optional due to an issue, such as de-oilization or environmental pollution. A device for producing renewable energy and storing energy in various manners is also an essential element. Recently, there has been an increase in interest of a lithium-ion secondary battery among various types of energy storage devices.

Recently, with the increase in electric vehicle (EV) user, there has been an increase in requirements for a state of health (SOH) for an EV battery and diagnosing and evaluating an abnormal state in conjunction with authentication of a state of a high voltage battery, authentication of a used EV, remanufacturing, and the like. The SOH means how much performance the battery has compared to the initial performance and is used as an index for providing a notification of remaining battery life and a current performance state.

Furthermore, it is required to diagnose an abnormal state for a high voltage battery pack mounted in a vehicle or the high voltage battery in a demounted state in various applications, such as issuing a battery certificate as well as remanufacturing, reusing, and recycling the battery of the EV.

As there is an increase in interest of the battery, the importance of a battery management system (BMS) is emerging. The BMS diagnoses and estimates a state, performance, and safety of the battery based on pieces of sensing information, such as a voltage, a current, and a temperature corresponding to a battery cell/pack. Particularly, voltage information is key information capable of diagnosing a state, aging, abnormal motion of the battery. Thus, accurately analyzing a voltage characteristic is very important for a battery abnormality diagnosis.

The battery model may be used in various fields, such as design of an electrode of a battery pack, cell design, performance and life prediction, stability and abnormality diagnosis, battery pack design.

The battery model may be roughly classified into physical-based models and empirical models.

The physical-based models are models for calculating a response of the battery in a numerical analysis method for Formulating a main electrical-electrochemical-thermal phenomenon or the like in the battery. The empirical models are models for representing a response of the battery using data fitting, data trend analysis, an equivalent circuit model, and the like based on experimental data.

Currently, research proceeds to the development of a ROM model to have high accuracy, while supplementing a slow calculation speed of a physical model. The subject matter described in this background section is intended to promote an understanding of the background of the disclosure and thus may include subject matter that is not already known to those of ordinary skill in the art. The statements in this section merely provide background information related to the present disclosure and may not constitute prior art.

### SUMMARY

The present disclosure has been made to solve the above-mentioned problems occurring in the prior art while advantages achieved by the prior art are maintained intact.

An aspect of the present disclosure provides a method for detecting abnormality in battery pack based on a battery model and an apparatus therefor.

Another aspect of the present disclosure provides a method for detecting abnormality in battery pack to detect whether the battery pack is abnormal based on a battery model on an on-board vehicle or via interworking with a cloud server and an apparatus therefor.

Another aspect of the present disclosure provides a method for detecting abnormality in battery pack to set a threshold based on a battery voltage error estimated using a battery model and compare the actually measured battery pack voltage deviation with the threshold to more accurately detect abnormality in battery pack and an apparatus therefor.

The technical problems to be solved by the present disclosure are not limited to the aforementioned problems. Any other technical problems not mentioned herein should be clearly understood from the following description by those having ordinary skill in the art to which the present disclosure pertains.

According to an aspect of the present disclosure, a computing device may include a memory configured to store instructions; and a processor. The processor may, by execute the instructions, set a battery model corresponding to a battery pack. The processor may estimate a battery voltage based on the set battery model. The processor may measure a real battery voltage. The processor may determine a battery pack voltage deviation based on the real battery voltage. The processor may determine a model estimation error based on the battery voltage and the real battery voltage. The processor may set a threshold based on the model estimation error. The processor may compare the battery pack voltage deviation with the threshold to determine whether the battery pack is abnormal.

As an embodiment, the processor may determine that the battery pack is abnormal based on the threshold being greater than the battery pack voltage deviation.

As an embodiment, the processor may determine the battery pack voltage deviation based on a state of charge (SOC) deviation and a polarization deviation.

As an embodiment, the processor may determine the model estimation error as a maximum error value between a model estimation voltage and an actually measured voltage.

As an embodiment, the model estimation error may include an SOC model error component defined by a difference value between a model estimation open circuit voltage (OCV); and an actually measured OCV and a polarization error component defined by a difference value between a battery model-based estimation polarization voltage and an actually measured polarization voltage. The processor may determine the maximum error value as a sum of a maximum value of the SOC model error component and a maximum value of the battery model-based estimation polarization voltage.

As an embodiment, the processor may apply certain weights to the maximum value of the SOC model error component and the maximum value of the battery model-based estimation polarization voltage, respectively to determine the threshold.

As an embodiment, the processor may adaptively determine the maximum value of the battery model-based estimation polarization voltage depending on SOC prediction. The processor may determine the maximum value of the battery model-based estimation polarization voltage in an SOC+ condition, when the SOC prediction is a high SOC boundary area. The processor may determine the maximum value of the battery model-based estimation polarization voltage in an SOC-condition, when the Soc prediction is a low SOC boundary area.

As an embodiment, the processor may receive and set information about the battery model corresponding to the battery pack from a cloud server interworking via a network.

As an embodiment, the computing device may be implemented as a server in a cloud environment.

As an embodiment, the computing device may be implemented in an on-board form of an electric vehicle (EV).

According to another aspect of the present disclosure, a method for diagnosing abnormality in battery pack of an electric vehicle (EV) in a computing device may include setting a battery model corresponding to the battery pack. The method may further include estimating a battery voltage based on the set battery model. The method may further include measuring a real battery voltage. The method may further include determining a battery pack voltage deviation based on the real battery voltage. The method may further include determining a model estimation error based on the battery voltage and the real battery voltage. The method may further include setting a threshold based on the model estimation error. The method may further include comparing the battery pack voltage deviation with the threshold to determine whether the battery pack is abnormal.

As an embodiment, the method may further include determining that the battery pack being abnormal based on that the threshold is greater than the battery pack voltage deviation.

As an embodiment, the method may further include determining the battery pack voltage deviation based on a state of charge (SOC) deviation and a polarization deviation.

As an embodiment, the method may further include determining the model estimation error as a maximum error value between a model estimation voltage and an actually measured voltage.

As an embodiment, the model estimation error may include an SOC model error component defined by a difference value between a model estimation open circuit voltage (OCV) and an actually measured OCV; and a polarization error component defined by a difference value between a battery model-based estimation polarization voltage and an actually measured polarization voltage. The method may further include determining the maximum error value as a sum of a maximum value of the SOC model error component and a maximum value of the battery model-based estimation polarization voltage.

As an embodiment, the method may further include determining the threshold by applying certain weights to the maximum value of the Soc model error component and the maximum value of the battery model-based estimation polarization voltage, respectively.

As an embodiment, the method may further include adaptively determining a maximum value of a battery model-based estimation polarization voltage according to Soc prediction. The method may further include determining the maximum value of the battery model-based estimation polarization voltage in an SOC+ condition, when the soc prediction is a high SOC boundary area. The method may further include determining the maximum value of the battery model-based estimation polarization voltage in an SOC-condition, when the Soc prediction is a low SOC boundary area.

As an embodiment, the computing device may interwork with a cloud server over a network. Information about the battery model corresponding to the battery pack may be received and set from the cloud server.

As an embodiment, the computing device may be implemented as a server in a cloud environment.

As an embodiment, the computing device may be implemented in an on-board form of the EV.

### BRIEF DESCRIPTION OF THE DRAWINGS

The above and other objects, features, and advantages of the present disclosure should be more apparent from the following detailed description taken in conjunction with the accompanying drawings:

FIG. 1 is a drawing for describing a configuration and a driving principle of an electric vehicle according to the present disclosure;

FIG. 2 is a drawing for describing the concept of an open circuit voltage (OCV) and polarization for calculating a battery voltage according to an embodiment of the present disclosure;

FIG. 3A is a flowchart for describing a method for diagnosing abnormality in battery pack based on a battery model in a battery pack abnormality diagnosis system according to an embodiment of the present disclosure;

FIG. 3B is a drawing for describing a method for calculating a battery model estimation polarization voltage based on state of charge (Soc) prediction according to an embodiment of the present disclosure;

FIG. 4 is a flowchart for describing a method for calculating a threshold for a battery pack abnormality diagnosis according to an embodiment of the present disclosure;

FIG. 5 is a block diagram for describing a configuration of a system for performing a battery pack abnormality diagnosis using diagnostic equipment for a battery pack mounted on an electric vehicle (EV) according to an embodiment of the present disclosure;

FIG. 6 is a block diagram for describing a system for performing a battery pack abnormality diagnosis based on a cloud according to an embodiment of the present disclosure;

FIG. 7 is a block diagram for describing a configuration of a system for performing a battery pack abnormality diagnosis based on an on-board vehicle according to an embodiment of the present disclosure; and

FIG. 8 illustrates a computing system according to an embodiment of the present disclosure.

### DETAILED DESCRIPTION

Hereinafter, some embodiments of the present disclosure are described in detail with reference to the drawings. In adding the reference numerals to the components of each drawing, it should be noted that the identical component is designated by the identical numerals even when they are displayed on other drawings. Further, in describing the embodiment of the present disclosure, a detailed description of well-known features or functions has been omitted in order not to unnecessarily obscure the gist of the present disclosure.

In describing the components of the embodiment according to the present disclosure, terms such as first, second, “A”, “B”, (a), (b), and the like may be used. These terms are merely intended to distinguish one component from another component, and the terms do not limit the nature, sequence, or order of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary are to be interpreted as having meanings equal to the contextual meanings in the relevant field of art and should not be interpreted as having ideal or excessively formal meanings unless clearly defined as having such in the present application. When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus.

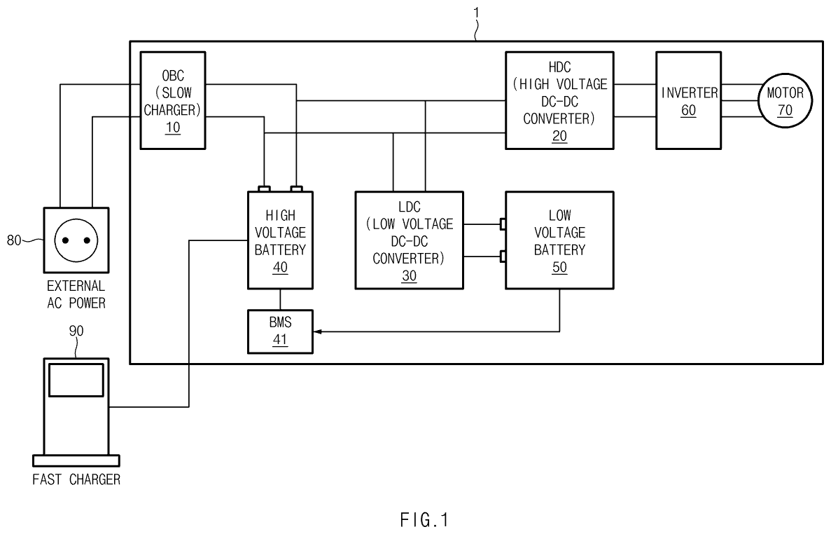

Hereinafter, embodiments of the present disclosure are described in detail with reference to FIGS. 1-8.

FIG. 1 is a drawing for describing a configuration and a driving principle of an electric vehicle according to the present disclosure.

Referring to FIG. 1, an electric vehicle 1 may be configured to include an on-board charger (OBC) 10, a high voltage DC-DC converter (HDC) 20, a low voltage DC-DC converter (LDC) 30, a high voltage battery 40, a battery management system (BMS) 41, a low voltage battery 50, an inverter 60, and a motor 70.

The OBC 10 may be a converter for receiving external AC power 80 and performing AC-DC conversion, which may be a part for slowly charging the high voltage battery 40.

The HDC 20 may be a part for performing DC-DC conversion of power from the high voltage battery 40 and supplying the power to the inverter 60.

The LDC 30 may be a converter system for dropping DC power of the high voltage battery 40 to convert the DC power into 12V low-voltage power requested by most parts of the electric vehicle 1, for example, headlights, wipers, a control unit, or the like and may supply the 12V low-voltage power to the low voltage battery 50.

The inverter 60 may be a power conversion device for driving the motor 70, which may be a part for converting DC into 3-phase AC to play a role in controlling a speed and a direction of the motor 70 and performing regenerative breaking.

The high voltage battery 40 may be charged by directly receiving power from a fast charger 90 for fast charging.

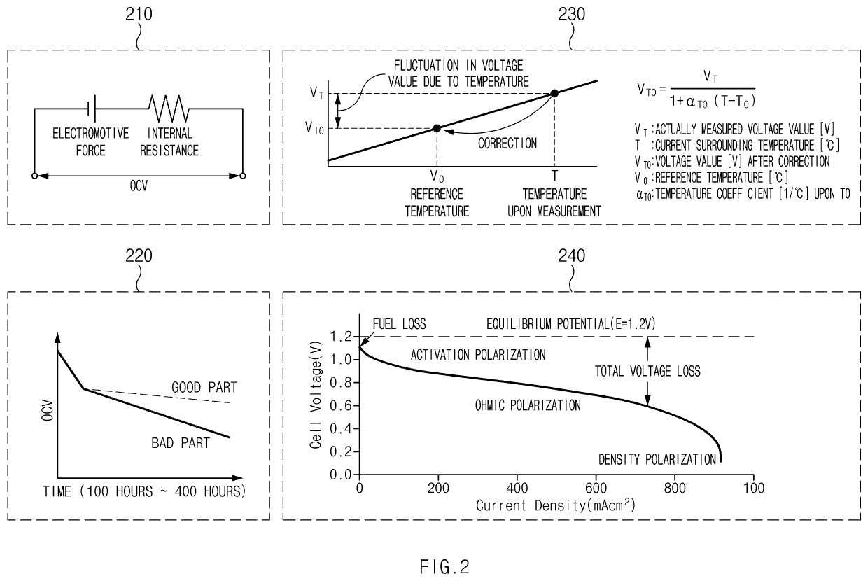

FIG. 2 is a drawing for describing the concept of an open circuit voltage (OCV) and polarization for calculating a battery voltage according to an embodiment of the present disclosure.

As shown in reference numeral 210, the OCV refers to a battery voltage, when a battery is not connected with a load. In other words, the OCV refers to a voltage measured at both ends of the battery in a state in which the circuit is open such that current does not flow in the battery. The battery has self-discharge characteristics. An OCV value is small according to the characteristics but is gradually degraded. Particularly, as shown in reference numeral 220, when there is a defect in the battery, self-discharge more increases.

The OCV of the battery fluctuates due to temperature. Thus, it is important to uniformly maintain a temperature environment, when measuring the OCV. As shown in reference numeral 230, temperature correction refers to converting an OCV measurement value into a voltage of a reference temperature.

It should be noted for a voltage change which occurs in a charging and discharging process to analyze performance of the battery. Particularly, there occurs a phenomenon in which the voltage more increases than the OCV upon charging and the voltage more decreases than the OCV upon discharging. Polarization is the cause of the phenomenon.

The polarization refers to several phenomena which occur in the surface of an electrode when the battery operates. The polarization may occur due to a factor, such as a change in density at a reaction point or skinning. A voltage loss occurs due to this, and this is called “overpotential” or a “polarization voltage”. As the overpotential is larger, a larger voltage is required to obtain current. This has an influence on efficiency and performance of the battery at once.

A real voltage of the battery may be described as the sum of the OCV and the polarization voltage.

As shown in reference numeral 240, the polarization voltage may be composed of the sum of the following three elements.
1) Activation polarization: a voltage required to overcome an energy barrier for initiating electrochemical reaction
2) Density (or mass transfer) polarization: a voltage loss which occurs in the process of moving ions or electrons in the battery.
3) Ohmic polarization: a voltage loss which occurs due to resistance of electrodes, electrolytes, and the other electrical components

A battery pack abnormality diagnosis system according to the present disclosure or a computing device for diagnosing abnormality in battery pack (hereinafter collectively referred to as a “battery pack abnormality diagnosis system”) may estimate an OCV using a model based on an SOC. The system may estimate a polarization voltage based on an equivalent circuit model (ECM). The system may then determine whether the battery pack is abnormal based on an error between a voltage estimated using a battery model and a real voltage.

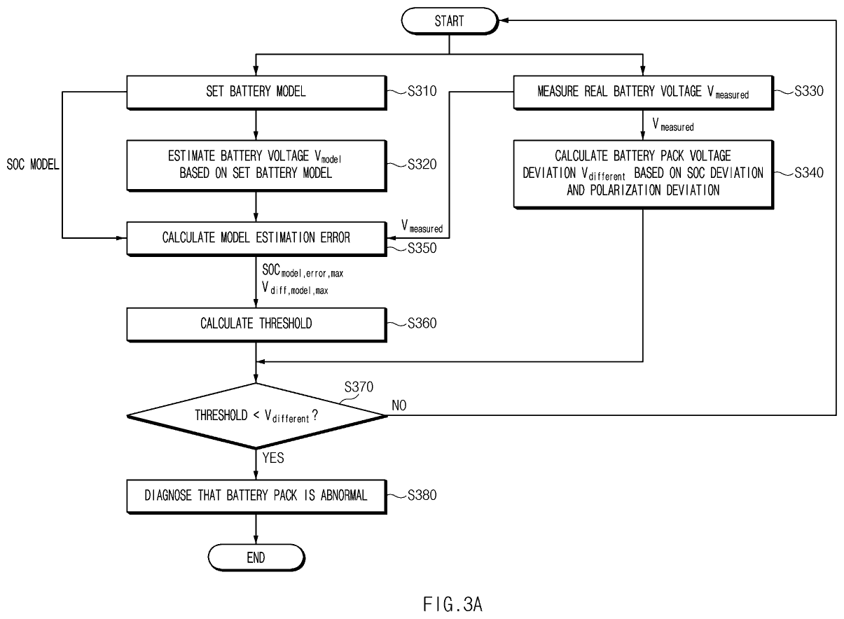

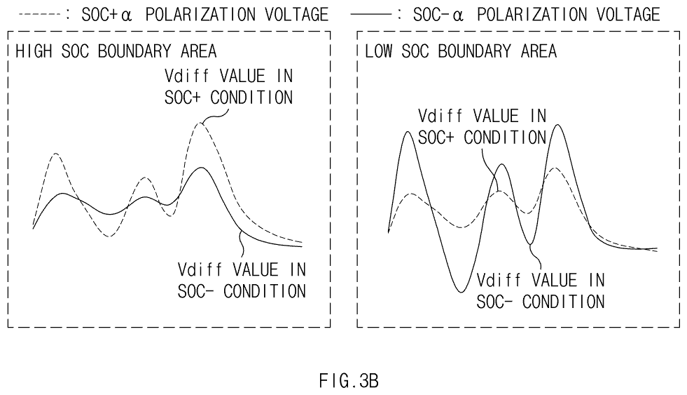

FIG. 3A is a flowchart for describing a method for diagnosing abnormality in battery pack based on a battery model in a battery pack abnormality diagnosis system according to an embodiment of the present disclosure. FIG. 3B is a drawing for describing a method for calculating a battery model estimation polarization voltage based on state of charge (SOC) prediction according to an embodiment of the present disclosure.

Referring to FIG. 3A, in S310, the battery pack abnormality diagnosis system may set a battery model. As an example, the battery model may include, but is not limited to, an equivalent circuit model (ECM) or an electrochemical model. The battery pack abnormality diagnosis system according to an embodiment may also set a state of charge (SOC) model.

In S320, the battery pack abnormality diagnosis system may estimate a battery voltage V_{model} based on the set battery model. Herein, V_{model} may be estimated based on at least one parameter among a battery soc, a current, and a temperature.

In S330, the battery pack abnormality diagnosis system may measure a real battery voltage V_{measured}.

In S340, the battery pack abnormality diagnosis system may calculate a battery pack voltage deviation V_{different} based on an SOC deviation and a polarization deviation.

In S350, the battery pack abnormality diagnosis system may calculate a model estimation error based on V_{model} and V_{measured}.

The model estimation error according to an embodiment may be calculated as a maximum error value between the model estimation voltage and the actually measured voltage. The model estimation error may comprise the sum of an SOC model error component, i.e., SOC_{model,error}, which is a difference value between a model estimation OCV and an actually measured OCV and a polarization error component, which is a difference value between a battery model estimation polarization voltage V_{diffmodel} and an actually measured polarization voltage V_{diff,real}. Thus, a maximum value of the model estimation error may correspond to the case in which each of the SOC model error and the polarization error is the maximum.

As an embodiment, the maximum value of the SOC model error component may be determined as a maximum value among SOC model errors of each cell (i=1, . . . , N). The maximum value of the polarization error component may be calculated as the case in which the actually measured polarization voltage V_{diff,real} is 0 and the battery model estimation polarization voltage V_{diff,real} is the maximum.

Because the battery model estimation polarization voltage is able to vary with SOC prediction as shown in FIG. 3B, it may be calculated according to whether the Soc prediction is a high SOC boundary area (SOC high) or a low SOC boundary area (SOC low). In other words, the battery model estimation polarization voltage may have a maximum value is an SOC+ condition, when the SOC prediction is the high SOC boundary area, and may have a maximum value in an SOC-condition, when the soc prediction is the low SOC boundary area.

In S360, the battery pack abnormality diagnosis system may calculate a threshold for determining whether the battery pack is abnormal.

As an example, the threshold may be calculated based on an SOC model error maximum value SOC_{model,error,max} and a battery model-based polarization error maximum value V_{diff,model,max}. In detail, the threshold may be calculated based a value obtained by applying certain coefficients (or weights) β1 and β2 to the SOC model error maximum value SOC_{model,error,max} and the battery model-based polarization error maximum value V_{diff,model,max}, respectively, and adding the Soc model error maximum value and the battery model-based polarization error maximum value to which β1 and β2 are applied.

As another example, the threshold may be calculated based on a difference value between a maximum voltage V_{model,max} and a minimum voltage V_{model,min}, which are estimated in response to a current soc, a current, and a temperature based on the battery model.

In S370, the battery pack abnormality diagnosis system may compare a magnitude of the battery pack voltage deviation V_{different} calculated in S340 with a magnitude of the threshold Threshold.

When Threshold is greater than V_{different} (YES in S370), in S380, the battery pack abnormality diagnosis system may diagnose that the battery pack fails (or is abnormal). A plurality of cells is configured as the battery pack. The cell in the battery pack has a tendency to deteriorate equally in general. Thus, when a voltage deviation of a specific cell in the battery pack is greater than the threshold, it may be determined that the cell fails. Thus, a failure in the battery pack may be diagnosed. In other words, when a real voltage deviation is greater than a maximum value of a voltage deviation set using the battery model, it may be diagnosed that the battery pack or the battery module fails.

As an embodiment, when a maximum error value, that is, SOC_{model,error,max} of the Soc model in which an SOC deviation and a polarization deviation are set for the cell of the battery pack is greater than a maximum value, i.e., V_{diff,model,max} of the polarization voltage deviated using the battery model, it may be described that the battery pack abnormality diagnosis system diagnoses abnormality.

As another embodiment, the battery abnormality diagnosis system may calculate the threshold and the voltage deviation, like the following formula, and may compare the threshold with the voltage deviation to determine whether the battery pack is abnormal.

$$Threshold = argmax ( {V}_{model , max} ( SOC , Current , Temperature ) - {V}_{model , min} ( SOC , Current , Temperature ) )$$

$$Voltage difference = ( {V}_{measure , max} - {V}_{measure , min} )$$

$$if Threshold < Voltage difference . battery failure occurs$$

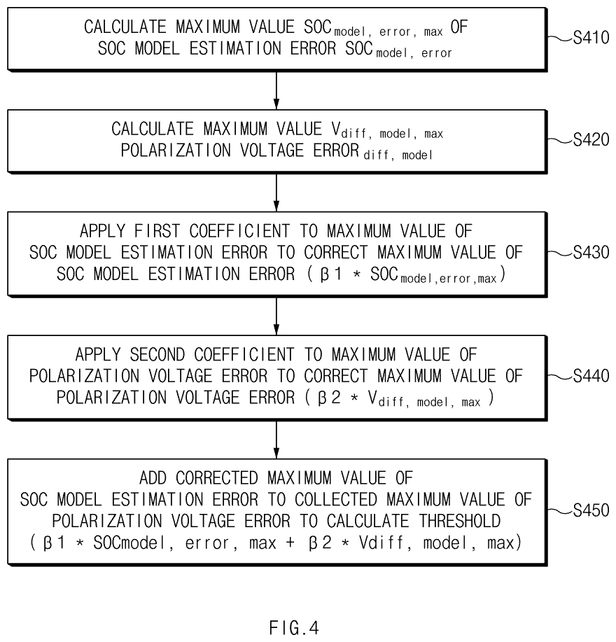

FIG. 4 is a flowchart for describing a method for calculating a threshold for a battery pack abnormality diagnosis according to an embodiment of the present disclosure

Referring to FIG. 4, in S410, a battery pack abnormality diagnosis system may calculate a maximum value SOC_{model, error, max} of an SOC model estimation error SOC_{model, error}.

In S420, the battery pack abnormality diagnosis system may calculate a maximum value V_{diff, model, max} of a polarization voltage error V_{diff, model}.

In S430, the battery pack abnormality diagnosis system may apply a first coefficient to the maximum value of the SOC model estimation error to correct the maximum value of the SOC model estimation error (β1*SOC_{model, error, max}).

In S440, the battery pack abnormality diagnosis system may apply a second coefficient to the maximum value of the polarization voltage error to correct the maximum value of the polarization voltage error (β2*V_{diff, model, max}).

In S450, the battery pack abnormality diagnosis system may add the corrected maximum value of the SOC model estimation error to the corrected maximum value of the polarization voltage error to calculate a threshold (β1*SOC_{model, error, max}+β2*V_{diff, model, max}).

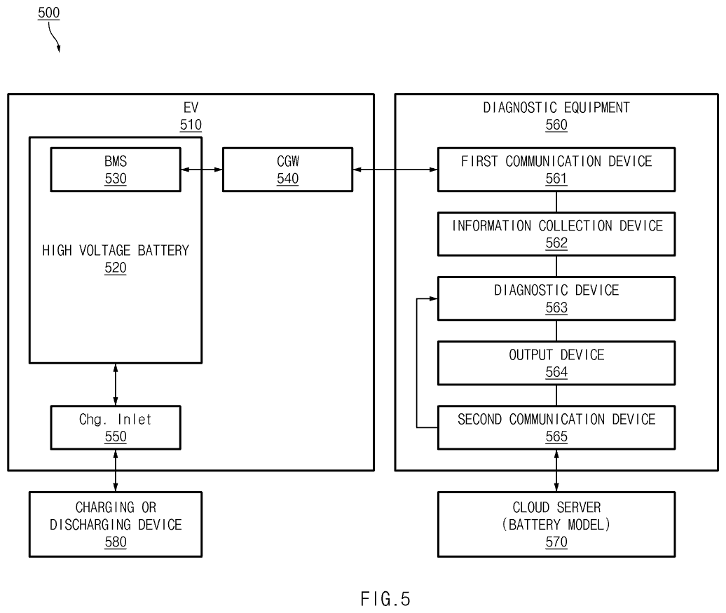

Hereinafter, a description is given of a configuration method of a battery pack abnormality diagnosis system according to various embodiments with reference to FIGS. 5, 6, and 7.

FIG. 5 is a block diagram for describing a configuration of a system for performing a battery pack abnormality diagnosis using diagnostic equipment for a battery pack mounted on an electric vehicle (EV) according to an embodiment of the present disclosure.

A battery pack abnormality diagnosis system 500 according to an embodiment may be roughly configured to include an EV 510, diagnostic equipment 560, a cloud server 570, and a charging or discharging device 580.

The EV 510 may be configured to include a high voltage battery 520, a BMS 530, a charging gateway (CGW) 540, and a charging inlet 550.

The diagnostic equipment 560 may be configured to include a first communication device 561, an information collection device 562, a diagnostic device 563, an output device 564, and a second communication device 565.

The BMS 530 of the high voltage battery 520 may perform communication with the first communication device 561 of the diagnostic equipment 560 via the CGW 540.

The information collection device 562 may collect sensing information, such as a voltage, a current, a temperature, or the like of the high voltage battery 520.

The diagnostic device 563 may perform a battery pack abnormality diagnosis based on the collected sensing information and the set battery model. Battery model-based battery pack abnormality diagnosis logic may be replaced with the above-mentioned description of the drawings.

The output device 564 may output the result of the battery pack abnormality diagnosis.

The second communication device 565 may be connected with the cloud server 570 over a network to obtain information about the battery model corresponding to the high voltage battery 520 mounted on the EV 510 from the cloud server 570 and provide the diagnostic device 563 with the obtained information.

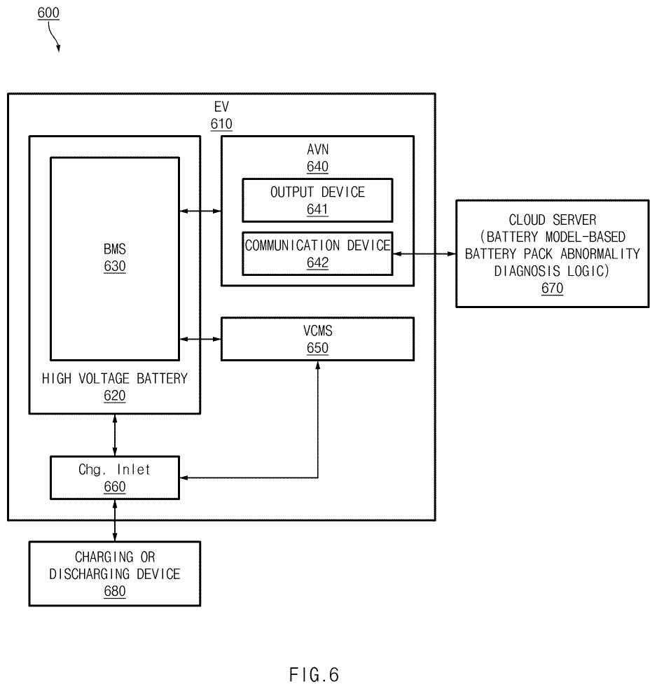

FIG. 6 is a block diagram for describing a system for performing a battery pack abnormality diagnosis based on a cloud according to an embodiment of the present disclosure.

A battery pack abnormality diagnosis system 600 according to an embodiment may be roughly configured to include an EV 610, a cloud server 670, and a charging or discharging device 680.

The EV 610 may be configured to include a high voltage battery 620, a BMS 630, audio video navigation (AVN) 640, a vehicle charging management system (VCMS) 650, and a charging inlet 660.

The VCMS 650 may be an electric vehicle charging controller for controlling and managing the overall charging system of the EV 610, which may communicate via the charging or discharging device 680 and the charging inlet 660 to control charging/discharging, when power is supplied from the outside of the EV 610 or supplying power to the outside. The VCMS 650 may be configured to include a charging management system (CMS) for controlling slow charging and fast charging and a powerline communication module (PCM) for controlling fast charging. The VCMS 650 may cooperatively control a related controller in a vehicle via the CMS and the PCM and may perform bidirectional communication with an external charger or discharger to control charging of the high voltage battery 620 or control discharging of power charged in the high voltage battery 620.

The AVN 640 may be configured to include an output device 641 and a communication device 642.

The BMS 630 may interwork with the cloud server 670 via the communication device 642 of the AVN 640.

The cloud server 670 may perform a battery model-based battery pack abnormality diagnosis based on sensing information, such as a current, a voltage, a temperature, or the like corresponding to the high voltage battery 620, which is received from the BMS 630. The cloud server 670 may obtain battery information including information about specifications of the high voltage battery 620 from the BMS 630 and may set the battery model based on the obtained battery information. The cloud server 670 may perform the loaded battery pack abnormality diagnosis logic based on the set battery model to perform diagnosis of abnormality in the battery pack.

The cloud server 670 may transmit the result of the battery pack abnormality diagnosis to the AVN 640. The AVN 640 may output the result of the battery pack abnormality diagnosis via the output device 641. The result of the battery pack abnormality diagnosis according to an embodiment may also be output via a cluster of the EV 610.

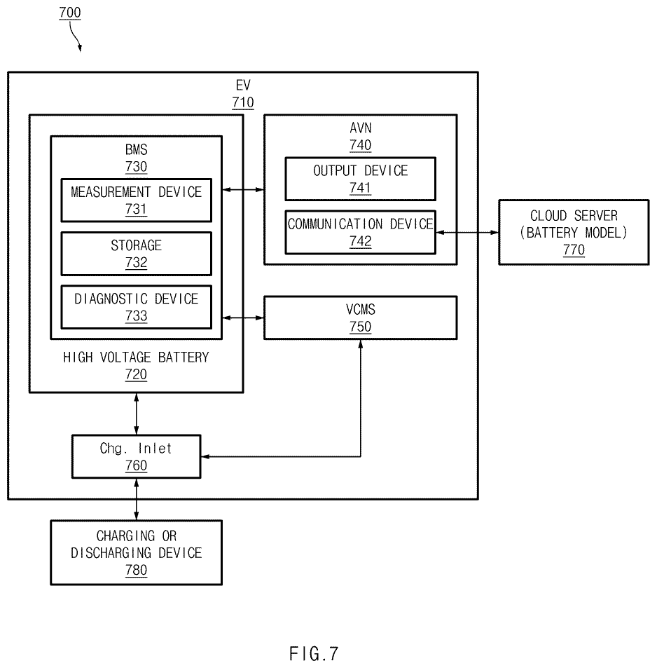

FIG. 7 is a block diagram for describing a configuration of a system for performing a battery pack abnormality diagnosis based on an on-board vehicle according to an embodiment of the present disclosure.

A battery pack abnormality diagnosis system 700 according to an embodiment may be roughly configured to include an EV 710, a cloud server 770, and a charging or discharging device 780.

The EV 710 may be configured to include a high voltage battery 720, a BMS 730, audio video navigation (AVN) 740, a vehicle charging management system (VCMS) 750, and a charging inlet 760.

The VCMS 750 may be an electric vehicle charging controller for controlling and managing the overall charging system of the EV 710, which may communicate via the charging or discharging device 780 and the charging inlet 760 to control charging/discharging, when power is supplied from the outside of the EV 710 or supplying power to the outside. The VCMS 750 may be configured to include a charging management system (CMS) for controlling slow charging and fast charging and a powerline communication module (PCM) for controlling fast charging. The VCMS 750 may cooperatively control a related controller in a vehicle via the CMS and the PCM and may perform bidirectional communication with an external charger or discharger to control charging of the high voltage battery 720 or control discharging of power charged in the high voltage battery 720.

The AVN 740 may be configured to include an output device 741 and a communication device 742.

The BMS 730 may interwork with the cloud server 770 via the communication device 742 of the AVN 740.

The BMS 730 may be configured to include a measurement device 731, a storage 732, and a diagnostic device 733.

The measurement device 731 may measure a current, a voltage, a temperature, or the like of the high voltage battery 720 using a voltage sensor, a current sensor, a temperature sensor, or the like which is provided and may record the measured sensing information in the storage 732.

The BMS 730 may obtain information about the battery model corresponding to the high voltage battery 720 from the cloud server 770 and may record the obtained information in the storage 732. Herein, the battery model may include an SOC model and an ECM and may be determined based on specifications of the high voltage battery 720.

The diagnostic device 733 may perform a battery pack abnormality diagnosis based on the sensing information and the battery model information, which are recorded in the storage 732.

The diagnostic device 733 may transmit the result of the battery pack abnormality diagnosis to the AVN 740. The AVN 740 may output the result of the battery pack abnormality diagnosis via the output device 741.

It is described in the embodiment of FIG. 7 that the battery pack abnormality diagnosis logic is implemented in the BMS 730, but this is only one embodiment. The battery pack abnormality diagnosis logic according to another embodiment may be implemented on a separate vehicle controller interworking with the BMS 730 via in-vehicle communication.

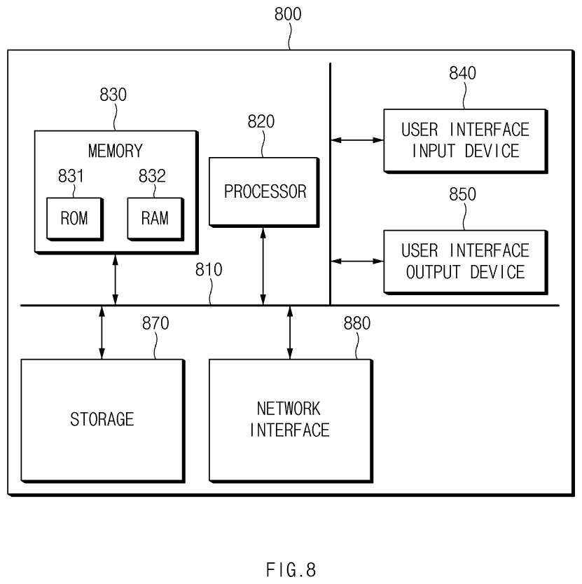

FIG. 8 illustrates a computing system according to an embodiment of the present disclosure.

Referring to FIG. 8, a computing system 800 may include at least one processor 820, a memory 830, a user interface input device 840, a user interface output device 850, a storage 870, and a network interface 880, which are connected with each other via a bus 810.

The network interface 880 according to an embodiment may perform at least one of diagnosis communication, inter-vehicle communication, and (or) communication with an external server. The network interface 880 may include a communication module (or a communication modem) for at least one of wired communication with an EV via a diagnosis cable, inter-vehicle communication for an inter-vehicle communication network, for example, CAN communication, or wireless communication via a mobile communication network.

The processor 820 may be a central processing unit (CPU) or a semiconductor device that processes instructions stored in the memory 830 and/or the storage 870. The memory 830 and the storage 870 may include various types of volatile or non-volatile storage media. For example, the memory 830 may include a Read Only Memory (ROM) 831 and a Random Access Memory (RAM) 832.

Thus, the operations of the method or the algorithm described in connection with the embodiments disclosed herein may be embodied directly in hardware, a software module executed by the processor 820, or in a combination thereof. The software module may reside on a storage medium (i.e., the memory 830 and/or the storage module 870) such as a RAM, a flash memory, a ROM, an EPROM, an EEPROM, a register, a hard disc, a removable disk, and a CD-ROM.

The storage medium may be coupled to the processor 820. The processor 820 may read out information from the storage medium and may write information in the storage medium. Alternatively, the storage medium may be integrated with the processor 820. The processor and the storage medium may reside in an application specific integrated circuit (ASIC). The ASIC may reside within a user terminal. As another method, the processor and the storage medium may reside as individual components in the EV, but this is only an embodiment. The processor and the storage medium may reside in a cloud server.

As an embodiment, the computing system 800 may be implemented to perform at least one function and method disclosed in FIGS. 1-7 described above and may be applied to at least one of the components of the above-mentioned battery pack abnormality diagnosis system.

The present technology may provide the method for detecting the abnormality in battery pack based on the battery model and the apparatus therefor.

Furthermore, the present technology may provide the method for detecting the abnormality in battery pack to detect whether the battery pack is abnormal based on the battery model on an on-board vehicle or via interworking with a cloud server and the apparatus therefor.

Furthermore, the present technology may provide the method for detecting the abnormality in battery pack to set a threshold based on a battery voltage error estimated using the battery model and compare the actually measured battery pack voltage deviation with the threshold to more accurately detect abnormality in battery pack and the apparatus therefor.

In addition, various effects ascertained directly or indirectly through the present disclosure may be provided.

Hereinabove, although the present disclosure has been described with reference to embodiments and the accompanying drawings, the present disclosure is not limited thereto, but may be variously modified and altered by those having ordinary skill in the art to which the present disclosure pertains without departing from the spirit and scope of the present disclosure claimed in the following claims.

Accordingly, embodiments of the present disclosure are intended not to limit but to explain the technical idea of the present disclosure, and the scope and spirit of the present disclosure is not limited by the above embodiments. The scope of the present disclosure should be construed based on the accompanying claims, and all the technical ideas within the scope equivalent to the claims should be included in the scope of the present disclosure.

1. A computing device for diagnosing abnormality in battery pack, the computing device comprising:
a memory configured to store instructions; and
a processor is configured, by executing the instructions, to:
set a battery model corresponding to a battery pack;
estimate a battery voltage based on the set battery model;
measure a real battery voltage;
determine a battery pack voltage deviation based on the real battery voltage;
determine a model estimation error based on the battery voltage and the real battery voltage;
set a threshold based on the model estimation error; and
compare the battery pack voltage deviation with the threshold to determine whether the battery pack is abnormal.

2. The computing device of claim 1, wherein the processor is configured to:
determine that the battery pack is abnormal based on the battery pack voltage deviation being greater than the threshold.

3. The computing device of claim 1, wherein the processor is configured to:
determine the battery pack voltage deviation based on a state of charge (SOC) deviation and a polarization deviation.

4. The computing device of claim 1, wherein the processor is configured to:
determine the model estimation error as a maximum error value between a model estimation voltage and an actually measured voltage.

5. The computing device of claim 4, wherein the model estimation error includes:
an SOC model error defined by a difference value between a model estimation open circuit voltage (OCV) and an actually measured OCV; and
a polarization error defined by a difference value between a battery model-based estimation polarization voltage and an actually measured polarization voltage, and
wherein the processor is configured to:
determine the maximum error value as a sum of a maximum value of the SOC model error and a maximum value of the battery model-based estimation polarization voltage.

6. The computing device of claim 5, wherein the processor is configured to:
apply certain weights to the maximum value of the SOC model error and the maximum value of the battery model-based estimation polarization voltage, respectively to determine the threshold.

7. The computing device of claim 6, wherein the processor is configured to:
adaptively determine the maximum value of the battery model-based estimation polarization voltage depending on SOC prediction;
determine the maximum value of the battery model-based estimation polarization voltage in a condition that adds the SOC prediction and a predetermined SOC, based on the SOC prediction included in a high SOC boundary area; and
determine the maximum value of the battery model-based estimation polarization voltage in a condition that substrates the predetermined SOC from the SOC prediction, based on the SOC prediction included in a low SOC boundary area.

8. The computing device of claim 1, wherein the processor is configured to:
receive and set information about the battery model corresponding to the battery pack from a cloud server interworking via a network.

9. The computing device of claim 1, wherein the computing device is implemented as a server in a cloud environment.

10. The computing device of claim 1, wherein the computing device is implemented in an on-board form of an electric vehicle (EV).

11. A method for diagnosing abnormality in battery pack of an electric vehicle (EV) in a computing device, the method comprising:
setting a battery model corresponding to the battery pack;
estimating a battery voltage based on the set battery model;
measuring a real battery voltage;
determining a battery pack voltage deviation based on the real battery voltage;
determining a model estimation error based on the battery voltage and the real battery voltage;
setting a threshold based on the model estimation error; and
comparing the battery pack voltage deviation with the threshold to determine whether the battery pack is abnormal.

12. The method of claim 11, further comprising:
determining that the battery pack is abnormal based on the battery pack voltage deviation being greater than the threshold.

13. The method of claim 11, further comprising:
determining the battery pack voltage deviation based on a state of charge (SOC) deviation and a polarization deviation.

14. The method of claim 11, further comprising:
determining the model estimation error as a maximum error value between a model estimation voltage and an actually measured voltage.

15. The method of claim 14, wherein the model estimation error includes:
an SOC model error defined by a difference value between a model estimation open circuit voltage (OCV) and an actually measured OCV; and
a polarization error defined by a difference value between a battery model-based estimation polarization voltage and an actually measured polarization voltage, and
wherein the method further comprises:
determining the maximum error value as a sum of a maximum value of the SOC model error and a maximum value of the battery model-based estimation polarization voltage.

16. The method of claim 15, further comprising:
determining the threshold by applying certain weights to the maximum value of the SOC model error and the maximum value of the battery model-based estimation polarization voltage, respectively.

17. The method of claim 16, further comprising:
adaptively determining a maximum value of a battery model-based estimation polarization voltage according to SOC prediction;
determining the maximum value of the battery model-based estimation polarization voltage in a condition that adds the SOC prediction and a predetermined SOC, based on the SOC prediction included in a high SOC boundary area;
determining the maximum value of the battery model-based estimation polarization voltage in a condition that substrates the predetermined SOC from the SOC prediction, based on the SOC prediction included in a low SOC boundary area.

18. The method of claim 11, wherein the computing device is configured to interwork with a cloud server over a network, and receive and set information about the battery model corresponding to the battery pack from the cloud server.

19. The method of claim 11, wherein the computing device is implemented as a server in a cloud environment.

20. The method of claim 11, wherein the computing device is implemented in an on-board form of the EV.
